(19) United States
(12) Patent Application Publication
(10) Pub. No.: US 2003/0049933 A1
(43) Pub. Date: Mar. 13, 2003

(54) Apparatus for handling liquid precursor material for semiconductor processing

(75) Inventors: Lawrence Chung-Lai Lei, Milpitas, CA (US); Eric Schieve, Palo Alto, CA (US)

Correspondence Address: APPLIED MATERIALS, INC., 2881 SCOTT BLVD. M/S 2061, SANTA CLARA, CA, 95050, US

(73) Assignee: APPLIED MATERIALS, INC.

(21) Appl. No.: 09/948,458

(22) Filed: Sep. 7, 2001

(51) Int. Cl. C23C 16/00; H01L 21/44

(52) U.S. Cl. 438/680; 118/715; 118/726

(57) ABSTRACT

Liquid phase material for a semiconductor fabrication process is simultaneously and continuously supplied to a plurality of processing tools from a liquid refill module rather than from a limited-capacity ampoule. A gas panel receives the flow of liquid material from the liquid refill module, and converts the liquid material into the gas phase. The gas panel includes a purge gas inlet and a waste outlet in communication with forelines of the semiconductor processing tools, such that vaporizer, flowmeter, and gas/liquid handling line components of the gas panel can periodically be effectively purged without contaminating other elements of the gas panel.

### BACKGROUND OF THE INVENTION

The present invention is directed to material handling systems and, more specifically, to systems for supplying liquid materials to semiconductor fabrication tools.

Semiconductor fabrication processes may include the use of chemical vapor deposition (CVD) to deposit a thin film of material on semiconductor wafers. CVD processes are often preferred for such applications due to their ability to provide highly uniform layers. A CVD process typically comprises introducing gases into a reaction chamber in the presence of a substrate, wherein the gases react and deposit a film on the surface of the substrate.

Some materials utilized in CVD originate as liquids and are subsequently evaporated and transported in the gas phase to the desired CVD reaction chamber. For example, titanium tetrachloride (TiCl₄) is used as a reactant gas during CVD to form deposit titanium-containing film layers onto a substrate surface. Tetrakisdimethyl-amidotitanium (TDMAT) is another metal-organic material used to deposit titanium-containing layers during CVD. Examples of uses for such titanium-containing films include liners for promoting adhesion between different components of interconnect structures, or barriers to diffusion of materials between components of interconnect structures.

CVD using TiCl₄ and TDMAT typically involves vaporization of liquid material, followed by transport of gas phase TiCl₄ or TDMAT to the reaction chamber using a carrier gas. During this process, care must be exercised to fully vaporize the liquid compound. If the compound is not fully vaporized and is delivered to the reaction chamber as a gas/liquid mixture, poor uniformity of the deposited film may result. Liquid components in the CVD reaction chamber can also create inconsistency problems from wafer to wafer, because liquid droplets deposited on the walls of the piping can later evaporate and give rise to fluctuation in vapor concentration in the chamber.

Once liquid CVD reactant is fully vaporized, care also must be taken to maintain the compound in the gas phase during transport to the reaction chamber. Condensation of TiCl₄ or TDMAT during this transport can lead to undesirable variability in the deposition process, and possibly to the failure of line components.

Conventionally, TDMAT is supplied to a CVD chamber from an ampoule structure. Such a conventional ampoule structure contains a limited quantity of TDMAT material, and once exhausted an ampoule must be replaced by a fresh one.

Replacement of the conventional ampoule supply may result in interruption of CVD processing, reducing system throughput. Although ampoule replacement is a relatively infrequent occurrence, CVD tool down time associated with ampoule change-out is undesirable.

In addition, TDMAT lines are very sensitive to air exposure. Should air accidentally be introduced into lines containing residual liquid TDMAT during ampoule change-out, replacement of clogged lines can be expensive and require additional tool down time to re-establish consistent flow.

Another limitation of conventional ampoule-based material supply systems is the relatively limited capacity of the ampoule. For this reason, an ampoule of a conventional material handling supply system is generally devoted to supplying a single CVD tool. Where multiple chambers are employed to perform the same CVD process, this exclusive chamber-ampoule relationship can create expense for purchase and maintenance of redundant supply hardware.

Accordingly, there is a need in the art for improved apparatuses and methods for supplying liquid precursor materials to semiconductor processing environments.

### SUMMARY OF THE INVENTION

The present invention provides apparatuses and methods for semiconductor processing, wherein liquid phase material for a semiconductor fabrication process is simultaneously and continuously supplied to a plurality of processing tools from a liquid refill module, rather than from a limited-capacity ampoule. In certain embodiments, a gas panel receives the flow of liquid material from the liquid refill module and converts the liquid material into the gas phase. The gas panel includes a purge gas inlet and a waste outlet in communication with a foreline of the semiconductor processing tool, such that vaporizer, flowmeter, and gas/liquid handling lines of the gas panel can effectively be periodically purged without contaminating other elements of the gas panel.

An embodiment of an apparatus for providing a material for a semiconductor process comprises a liquid refill module having an inlet configured to receive the material in liquid phase from a bulk reservoir, and an outlet configured to continuously flow the material in liquid phase to at least one of first and second semiconductor processing chambers. The liquid refill module further comprises a first tank, a second tank, and a fluid inlet valve in fluid communication with the bulk reservoir and one of the first tank and the second tank. A fluid outlet valve is in fluid communication with the semiconductor processing chamber and one of the first tank and the second tank. The fluid inlet valve and the fluid outlet valve are selectively operable to allow the first tank to provide liquid material to the semiconductor processing chambers while the second tank is being filled with liquid phase material from the bulk reservoir, and to allow the second tank to provide liquid material to the semiconductor processing chambers while the first tank is being filled with liquid phase material from the bulk reservoir.

An embodiment of a method of supplying a material to a semiconductor process comprises storing a bulk quantity of liquid phase material in a reservoir, and flowing the liquid phase material from the reservoir to a first tank of a liquid refill module while a second tank of the liquid refill module flows the liquid phase material to at least one of a first semiconductor processing tool and a second semiconductor processing tool. The liquid phase material is flowed from the reservoir to the second tank while the first tank of the liquid refill module flows the liquid phase material to at least one of the first semiconductor processing tool and the second semiconductor processing tool.

These and other embodiments of the present invention, as well as its advantages and features, are described in more detail in conjunction with the text below and attached figures.

### BRIEF DESCRIPTION OF THE DRAWINGS

FIG. 1 is a schematic depiction of an embodiment of a chemical vapor deposition system in accordance with the present invention;

FIG. 2 shows a detailed schematic view of an embodiment of the dual tank liquid refill (DTLR) module of the CVD system shown in FIG. 1;

FIG. 3A is schematic flow diagram of an embodiment of a gas panel module in accordance with the present invention;

FIG. 3B is a plan view of the gas panel shown in FIG. 3A;

FIG. 3C is a perspective view of the gas panel shown in FIG. 3A;

FIG. 4 is a flow chart showing the steps of material handling performed by the gas panel of FIGS. 3A-C;

FIG. 5 is a schematic flow diagram of an embodiment of a CVD chamber receiving a flow of materials from the gas panel shown in FIGS. 3A-C;

FIG. 6 is a front sectional view of one type of a vaporizer structure;

FIG. 7 is a sectional view of the vaporizer unit of FIG. 6 taken along line 3-3 in FIG. 6; and

FIG. 8 is a schematic sectional view of the vaporizer unit of FIGS. 6 and 7 showing its temperature control mechanism.

### DESCRIPTION OF THE SPECIFIC EMBODIMENTS

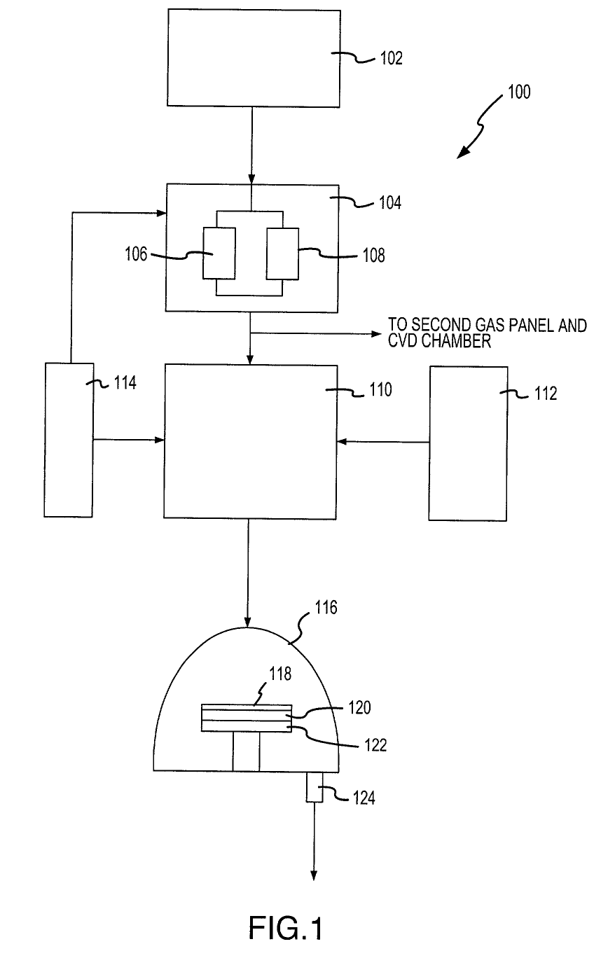

FIG. 1 is a schematic depiction of a chemical vapor deposition system in accordance with one embodiment of the present invention. System 100 comprises TDMAT reservoir 102 wherein large volumes of liquid TDMAT are stored, typically enough for an entire fabrication facility featuring a number of CVD systems.

Reservoir 102 feeds liquid TDMAT to dual tank liquid refill (DTLR) module 104. DTLR 104 comprises first tank 106 and second tank 108, each having a relatively large capacity. For example, in certain embodiments in accordance with the present invention, first tank 106 and second tank 108 have combined capacity of approximately 20 liters. This is to be compared with a conventional ampoule structure having a typical capacity of approximately 900 ml.

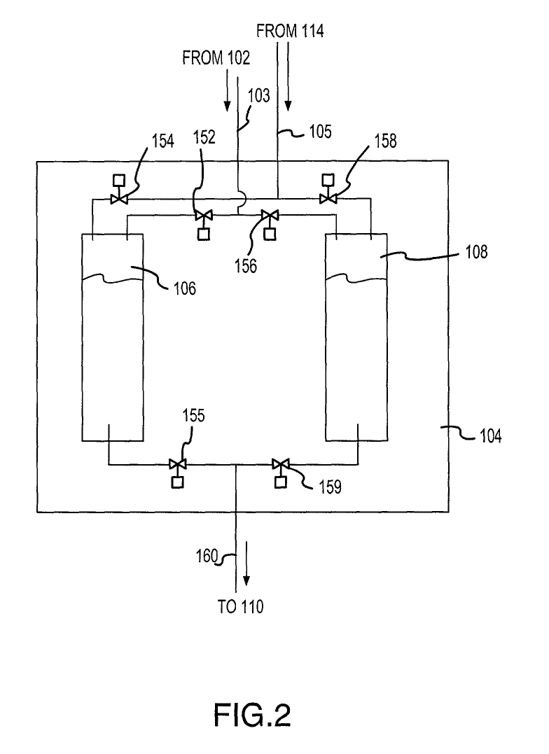

As discussed in detail below in connection with FIG. 2, first tank 106 and second tank 108 are each selectively in fluid communication with reservoir 102. DTLR 104 also receives a flow of an inert carrier gas from gas supply system 114.

First tank 106 and second tank 108 of DTLR 104 are each also in selective communication with gas panel 110. As shown in FIG. 1, DTLR 104 may simultaneously be in fluid communication with a second gas panel and associated semiconductor processing tool and chamber.

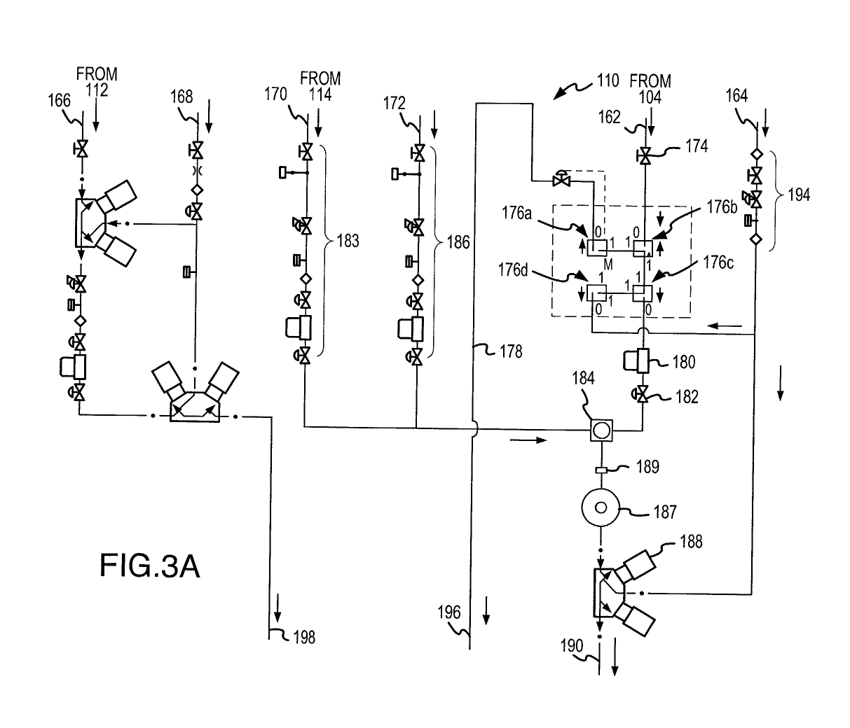

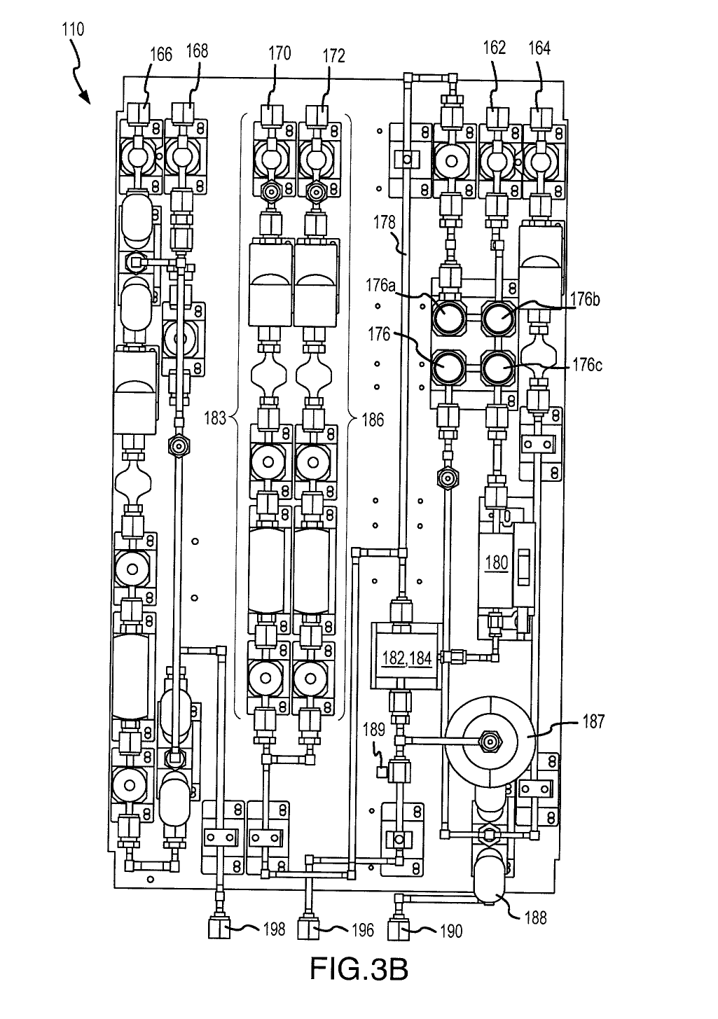

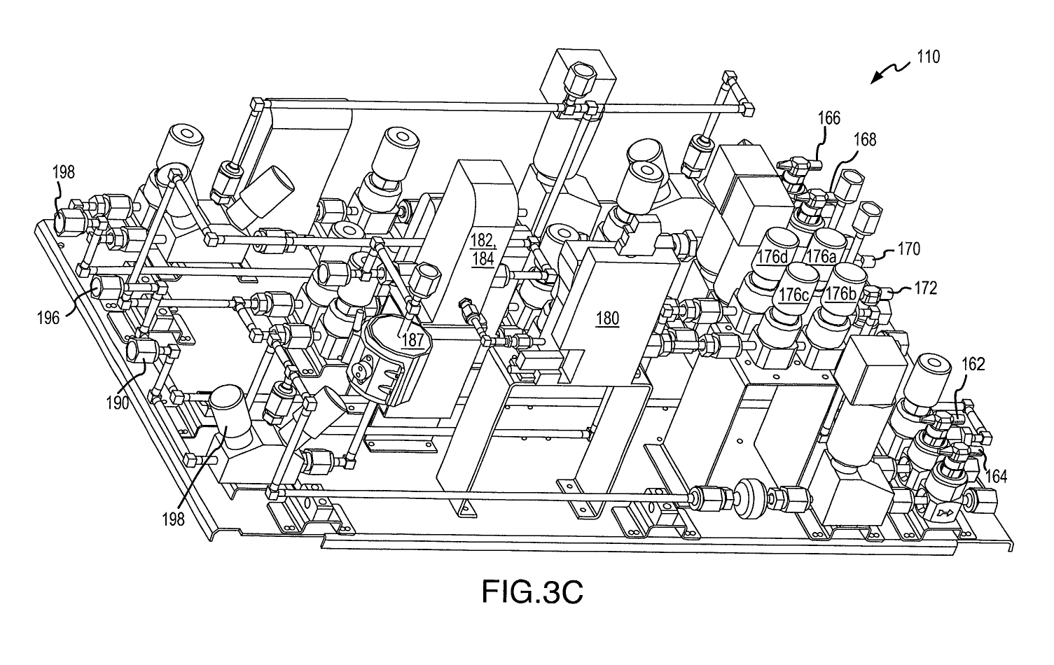

Gas panel 110 receives a flow of an inert carrier gas from gas supply system 114, and a flow of a cleaning gas from cleaning gas supply 112. As discussed in detail below in connection with FIGS. 3A-C, gas panel 110 receives liquid TDMAT from DTLR 102 and converts this liquid material into the gas phase. Gas panel 110 then flows the gaseous TDMAT to CVD chamber 116, where it can form metal-organic TiN (MOTiN) layer 118 on wafer 120 supported by heater 122. Effluent from CVD chamber 116 is exhausted through foreline 124.

FIG. 2 shows a detailed schematic view of DTLR 104 of FIG. 1. DTLR 104 includes liquid inlet 103, gas inlet 105, first tank 106, second tank 108, and outlet 160. First tank 106 is in fluid communication with TDMAT reservoir 102 through first liquid inlet valve 152. First tank 106 is in fluid communication with a pressurized inert carrier gas through first gas inlet valve 154. First tank 106 is in fluid communication with DTLR outlet port 160 through first outlet valve 155.

Second tank 108 is in fluid communication with TDMAT reservoir 102 through second liquid inlet valve 156. Second tank 108 is in fluid communication with inert carrier gas source 114 through second gas inlet valve 158. Second tank 108 is in fluid communication with DTLR outlet port 160 through second outlet valve 159.

The configuration just described allows DTLR 104 to continually provide liquid TDMAT to gas panel 110. Specifically, under the conditions summarized in TABLE A below, first tank 106 of DTLR 104 can provide liquid TDMAT to gas panel 110 through outlet port 160 while second tank 108 is being refilled from reservoir 102.

TABLE A

| COMPONENT | STATE |
|---|---|
| First liquid inlet valve 152 | closed |
| Second liquid inlet valve 156 | open |
| First gas inlet valve 154 | open |
| Second gas inlet valve 158 | closed |
| First outlet valve 155 | open |
| Second outlet valve 159 | closed |

Conversely, TABLE B shows the conditions under which second tank 108 of DTLR 104 can provide liquid TDMAT to gas panel 110 through outlet port 160 while first tank 106 is being refilled with liquid TDMAT from TDMAT reservoir 102.

TABLE B

| COMPONENT | STATE |
|---|---|
| First liquid inlet valve 152 | open |
| Second liquid inlet valve 156 | closed |
| First gas inlet valve 154 | closed |
| Second gas inlet valve 158 | open |
| First outlet valve 155 | closed |
| Second outlet valve 159 | open |

Repeated alteration between the configurations of TABLES A and B enables DTLR 104 to provide a continuous supply of liquid TDMAT to gas panel 110. Moreover, tanks 106 and 108 are of sufficient capacity that DTLR 104 may also simultaneously supply TDMAT liquid to a second gas panel and associated CVD processing tool and chamber.

FIG. 3A shows a schematic flow diagram of an embodiment of gas panel 110 of FIG. 1. FIG. 3B is a plan view of the gas panel shown in FIG. 3A. FIG. 3C is a perspective view of the gas panel shown in FIG. 3A.

Gas panel 110 includes liquid TDMAT inlet port 162 in fluid communication with outlet port 160 of DTLR 14. Gas panel 110 also includes TDMAT purge gas port 164, cleaning gas inlet port 166, cleaning gas purge port 168, first carrier gas inlet port 170, and second carrier gas inlet port 172.

During operation of gas panel 110, liquid TDMAT inlet at port 162 flows through manual valve 174 and pneumatic valves 176 b and 176 c. The liquid TDMAT then flows past liquid flow meter 180, which measures the amount of liquid flowing therethrough. Liquid TDMAT then flows through pneumatic valve 182 into vaporizer 184.

While liquid TDMAT flows to vaporizer 184, inert carrier gases are inlet to gas panel 110 through first and second carrier gas inlet ports 170 and 172, respectively. First and second carrier gases are flowed through first and second valve/flow meter networks 183 and 186 respectively to vaporizer 184. The lines for networks 183 and 186, may comprise stainless steel tubing or the like. In order to vaporize the liquid TDMAT in vaporizer 184, the carrier gas is preferably a combination of inert gases such as helium and nitrogen. For purposes of this patent application, the term carrier gas thus shall be understood to refer to an inert gas or to a combination of inert gases.

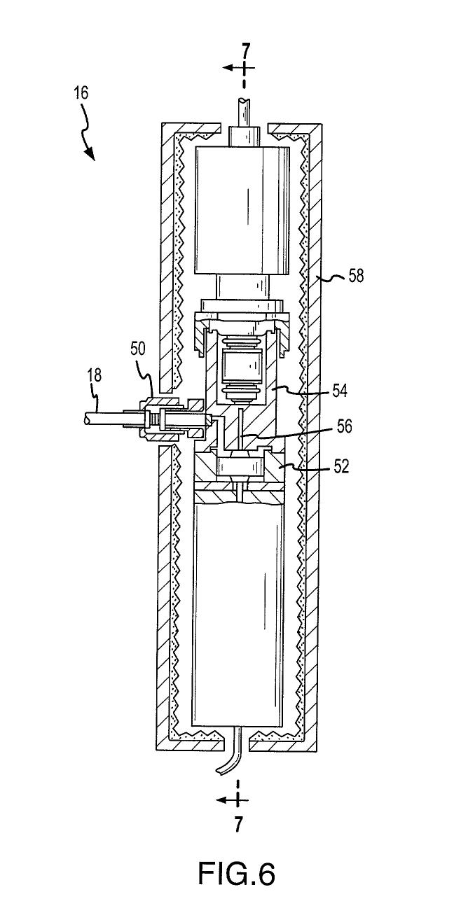

The flow of one or both of the inert carrier gases through vaporizer 184 converts liquid TDMAT to the vapor phase. Specifically, liquid TDMAT is atomized by venturi injection into the carrier gas stream. The structure and function of one embodiment of vaporizer unit is described in detail below in conjunction with FIGS. 6-8.

Vaporizer 184 includes elements having relatively small sizes that may occasionally become obstructed. In the event that vaporizer 184 becomes clogged or otherwise ceases to properly function, TDMAT remaining in the liquid phase will accumulate. Accordingly, gas panel embodiment 110 of FIGS. 3A-3C also includes liquid detector 189 located immediately downstream of vaporizer 184. Upon detection of liquid material, detector 189 will emit an electrical signal alerting the operator to a possible problem.

Once liquid TDMAT has been homogeneously converted to the gas phase in vaporizer 184, the atomized TDMAT is flowed through superheater structure 187 and uniformly heated to maintain homogeneity of its vapor phase. Gaseous TDMAT is then flowed through three-way valve 188 to TDMAT outlet port 190 of gas panel 110.

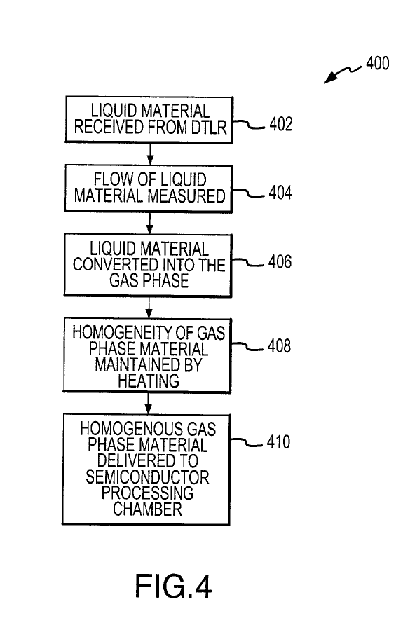

FIG. 4 is a flow chart summarizing the general sequence of steps 400 performed by the gas panel during the flow of TDMAT material therethrough. In first step 402, the gas panel receives TDMAT in liquid form from the DTLR. In second step 404, the gas panel measures the flow of liquid TDMAT. In third step 406 the gas panel atomizes the liquid TDMAT. In fourth step 408 the gas panel maintains an elevated temperature of the vaporized TDMAT to ensure a homogenous gas phase. In fifth step 408, the gas panel flows the homogenous gas phase TDMAT to the CVD chamber for deposition of a Ti-containing material upon a wafer.

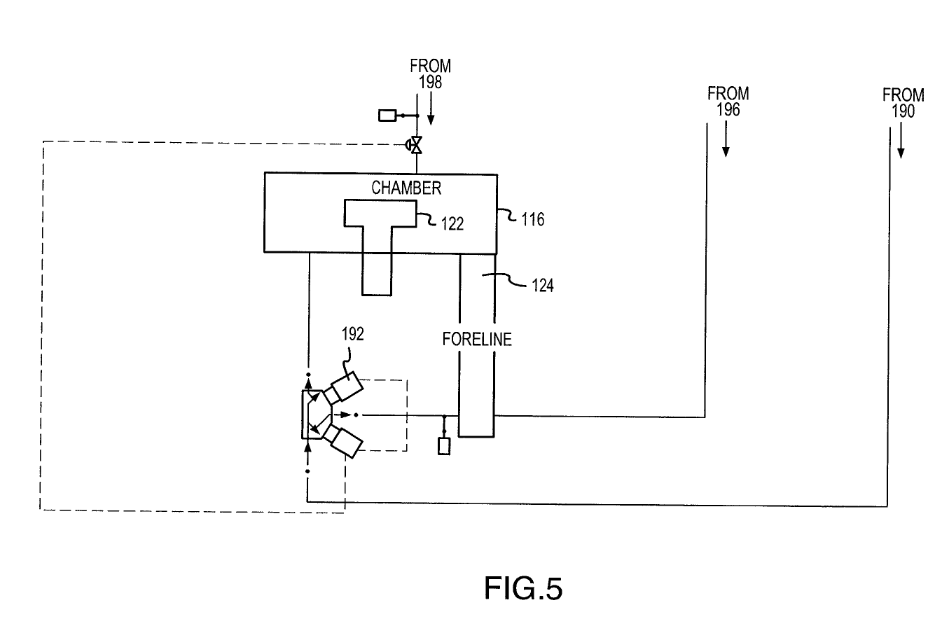

As shown in FIG. 5, TDMAT outlet port 190 of gas panel 110 is in fluid communication with three-way valve 192 of CVD chamber 116. In one setting, three-way valve 192 allows gaseous TDMAT to flow from gas panel outlet port 190 to CVD chamber 116 for deposition upon a wafer. In another setting, three-way valve 192 diverts materials flowed from TDMAT outlet port 190 away from CVD chamber 116 directly to foreline 124. The flow of inlet TDMAT gas directly to foreline 124 is generally useful during the process of stabilizing the gas flow prior to its introduction into the chamber.

As previously described, upon exposure to atmospheric oxygen, TDMAT rapidly undergoes reaction to form a powder. Because of this air-sensitive character, and because only small volumes of TDMAT are consumed during CVD of thin films, narrow gauge tubing and valves are present in the gas panel and thus the portion of the gas panel that handles TDMAT may become clogged.

In order to facilitate periodic purging of TDMAT-handling lines, valves, and other structures such as flowmeters and vaporizers, gas panel 110 further includes purge gas inlet port 164. Purge gas is supplied under pressure to port 164. The purge gas (typically N₂) is devoid of oxygen and therefore does not cause the TDMAT to form a powder upon exposure.

Purge gas inlet to gas panel 110 via TDMAT purge gas port 164 is conveyed to three-way valve 188 through valve network 194. Where purging of TDMAT is desired, the flow of liquid TDMAT is halted at valve 174, and three-way valve 188 is configured to flow N₂ purge gas back through vaporizer structure 184, liquid flow meter 180, and pneumatic valves 176a-b. Solidified TDMAT material dislodged and carried by the pressurized flow of purge gas is then shunted through gas panel disposal line 178 and out of waste outlet 196 of gas panel 110.

As shown in FIG. 5, waste outlet 196 of gas panel 110 is in fluid communication with foreline 124 of CVD chamber 116. This allows waste materials dislodged by the purge gases to be disposed of through foreline 124 of CVD chamber 116.

Returning to prior FIGS. 3A-3C, gas panel 110 of FIG. 3A also includes cleaning gas inlet port 166 and cleaning gas purge port 168. Cleaning gas inlet port 166 allows the gas panel to receive corrosive gases utilized in cleaning residues from CVD chamber 116, and to pass these corrosive gases to CVD chamber 116 through cleaning gas outlet port 198. Cleaning gas purge port 168 allows a subsequent flow of an inert gas to purge the contents of the cleaning gas-handling elements of gas panel 110.

As previously described, flow of one or both of the inert carrier gases through a vaporizer structure converts the liquid TDMAT to the vapor phase. Specifically, liquid TDMAT is first atomized by venturi injection into the carrier gas stream. Next, the atomized TDMAT is uniformly heated to ensure homogeneity of its vapor phase.

Turning now to FIGS. 6-8, embodiment 16 of a vaporizer unit for converting the liquid phase material to vapor phase is described. Vaporizer unit 16 comprises a liquid inlet 50 for receiving a desired liquid such as TDMAT. Liquid line 18 is operably connected to liquid inlet 50 to allow the transportation of liquid TDMAT to vaporizer unit 16. A control valve 52 operates to control the amount of liquid TDMAT passing therethrough. Liquid TDMAT proceeds through a vaporizer passageway 56 and into a vaporization valve 54.

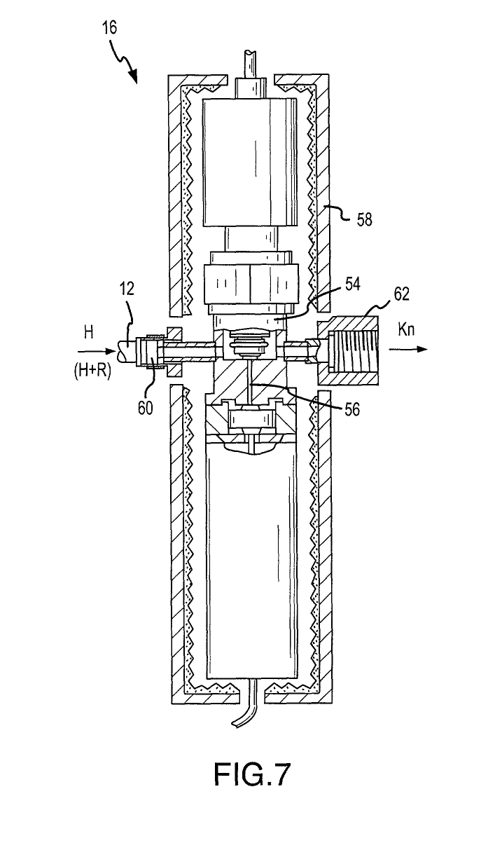

FIG. 7 is a sectional view of the vaporizer unit of FIG. 6 taken along line 3-3 in FIG. 6. As best seen in FIG. 7, vaporizer unit 16 further includes a carrier gas inlet 60 as shown here operably attached to carrier gas line 12. As the carrier gas enters vaporizer unit 16, it proceeds into and through vaporization valve 54. The carrier gas transports at least partially vaporized TDMAT through vaporization valve 54 and a liquid/gas TDMAT mixture exits a vaporizer unit outlet 62. Like the lines for networks 183 and 186, liquid gas mixture line 20 and product gas line 24 may comprise stainless steel tubing or the like. In one embodiment, lines 12, 13, 20 and 24 comprise ¼ inch diameter tubing, and line 18 comprises ⅛ inch diameter tubing.

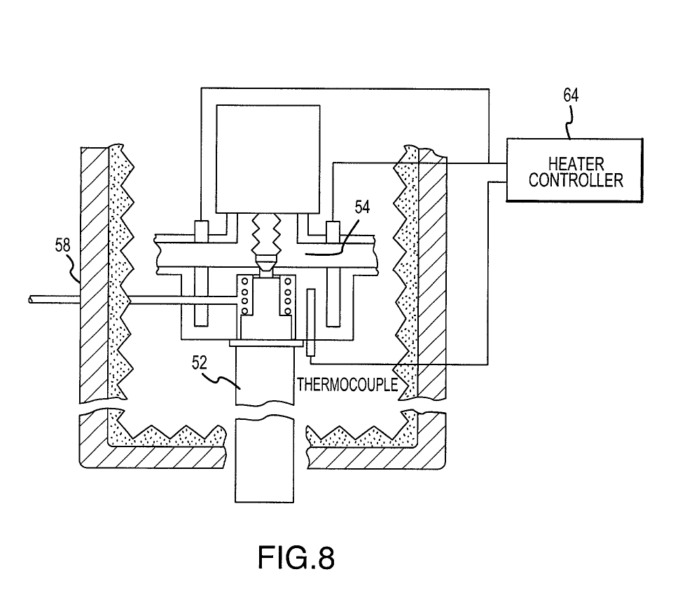

FIG. 8 is a schematic sectional view of the vaporizer unit of FIGS. 6 and 7 showing its temperature control mechanism. FIG. 8 depicts temperature-controlled housing structure 58 enclosing control valve 52 and vaporization valve 54. As seen in FIG. 8, a temperature control mechanism or heater controller 64 is operably attached to housing structure 58 to maintain a thermostatic condition inside housing structure 58. By controlling the temperature within housing structure 58, preferably at an elevated temperature between about 50 ° C. and about 200° C., and more preferably, between about 70° C. and about 90° C., TDMAT can be at least partially vaporized. Alternatively, TDMAT is at least partially vaporized by its contact with the carrier gas.

The preceding discussion in conjunction with FIGS. 6-8 describes an embodiment of a vaporizer unit according to the present invention. A more detailed description is provided in U.S. Pat. No. 5,440,887 and U.S. Pat. No. 5,272,880, the complete disclosures of which have been previously incorporated by reference.

Embodiments of methods and systems for performing chemical vapor deposition in accordance with the present invention offer a number of advantages over conventional systems. For example, while conventional ampoule-based systems require halting of the CVD process to allow periodic change-out, embodiments in accordance with the present invention to allow for continuous semiconductor processing without interruption for ampoule replacement. Another benefit of material handling systems in accordance with embodiments of the present invention is reduction in the danger of mishandling of liquid TDMAT leading to evacuation of the whole ampoule and clogging of material handling lines of the gas panel.

Another advantage of embodiments of systems and methods of the present invention is that TDMAT may be shown in a multiple chamber processing environment. Rather than requiring each ampoule of liquid material be devoted to supplying a single processing chamber, in accordance with an embodiment of the present invention each DTLR may supply a pair or more of CVD processing tools, thereby substantially reducing costs associated with purchase and maintenance of capital equipment.

A further advantage of systems and methods in accordance with the present invention is improved pump and purge capabilities. Specifically, pump/purge ports of the gas panel allow easy servicing of the liquid injection valve and the liquid flow meter in the event of clogging. As TDMAT is not very volatile, evacuation of the material is difficult once clogging of lines has occurred. Moreover, human contact with the liquid TDMAT is to be avoided due to safety concerns. The present design provides for safe and non-invasive detection of liquids present in the apparatus.

Many other equivalent or alternative embodiments of the present invention will be apparent to those skilled in the art. Thus while the above description relates to a system for handling TDMAT, other liquid phase materials may require conversion to the gas phase during semiconductor processing. For example, TiCl₄, tetraethylorthosilicate (TEOS), and triethylphosphate (TEPO) are other examples of materials that can be handled in accordance with embodiments of the present invention.

Having filly described several embodiments of the present invention, many other equivalent or alternative embodiments of the present invention will be apparent to those skilled in the art. These equivalents and alternatives are intended to be included within the scope of the present invention.

What is claimed is:

1. An apparatus for providing a liquid material for use in a semiconductor process, the apparatus comprising:
a liquid refill module having,
an inlet configured to receive the material in liquid phase from a bulk reservoir,
an outlet configured to continuously flow the material in liquid phase to at least one of first and second semiconductor processing chambers;
a first tank;
a second tank;
a fluid inlet valve in fluid communication with the bulk reservoir and one of the first tank and the second tank; and
a fluid outlet valve in fluid communication with the semiconductor processing chamber and one of the first tank and the second tank, the fluid inlet valve and the fluid outlet valve selectively operable to allow the first tank to provide liquid material to the semiconductor processing chambers while the second tank is being filled with liquid phase material from the bulk reservoir, and to allow the second tank to provide liquid material to the semiconductor processing chambers while the first tank is being filled with liquid phase material from the bulk reservoir.

2. The apparatus of claim 1 further comprising a pressurized inert gas supply system, the pressurized inert gas supply system in fluid communication with the liquid refill module to convey the liquid phase material from the refill module to the processing chambers.

3. The apparatus of claim 2 wherein the pressurized inert gas supply system is in selective fluid communication with the first tank and the second tank through a push gas inlet valve.

4. The apparatus of claim 1 firther comprising a gas panel including,
a liquid inlet configured to receive the flow of liquid phase material from the liquid refill module,
a vaporizer for converting the liquid phase material into the gas phase; and
a gas outlet configured to supply a flow of the gas phase material to the semiconductor processing chambers.

5. The apparatus of claim 4 wherein the gas panel further comprises a liquid flow meter configured to detect a rate of flow of the liquid phase material to the vaporizer.

6. The apparatus of claim 4 wherein the gas panel further comprises a liquid sensor positioned downstream of the vaporizer to detect liquid resulting from incomplete conversion of the liquid phase material to the gas phase.

7. The apparatus of claim 4 further comprising a pressurized inert gas supply system in fluid communication with the liquid refill module to convey the liquid phase material from the refill module to the liquid inlet, the inert gas supply system also in fluid communication with the vaporizer to promote atomization of the liquid phase material.

8. The apparatus of claim 7 wherein the gas panel further comprises:
a purge gas inlet in fluid communication with the pressurized inert gas system; and
a waste outlet in selective fluid communication with the pressurized inert gas system through the vaporizer, such that application of pressurized inert gas to the purge gas inlet forces accumulated material to the waste outlet.

9. The apparatus of claim 8 wherein:
the material is selected from the group consisting of titanium tetrachloride, tetrakisdimethyl-amidotitanium, tetraethylorthosilicate, and triethylphosphate;
the semiconductor processing chambers are CVD chambers; and
the waste outlet is in fluid communication with forelines of the CVD chambers.

10. A method of supplying a material to a semiconductor process, the method comprising:
storing a bulk quantity of liquid phase material in a reservoir;
flowing the liquid phase material from the reservoir to a first tank of a liquid refill module while a second tank of the liquid refill module flows the liquid phase material to at least one of a first semiconductor processing tool and a second semiconductor processing tool; and
flowing the liquid phase material from the reservoir to the second tank while the first tank of the liquid refill module flows the liquid phase material to at least one of the first semiconductor processing tool and the second semiconductor processing tool.

11. The method of claim 10 further comprising converting the liquid phase material into the gas phase prior to introducing the material to the semiconductor processing tools.

12. The method of claim 11 wherein converting the material to the gas phase comprises:
atomizing the liquid phase material; and
maintaining the gas phase material at an elevated temperature.

13. The method of claim 12 further comprising providing a liquid sensor downstream of a point of atomization of the liquid phase material to detect an accumulation of liquid resulting from incomplete conversion of the liquid phase material to the gas phase.

14. The method of claim 10 further comprising flowing an inert gas into one of the first tank and the second tank in order to flow the liquid phase material to the at least first and second semiconductor processing tools.

15. The method of claim 10 wherein:
storing a bulk quantity of the liquid phase precursor material in a reservoir comprises storing a bulk quantity of one of titanium tetrachloride, tetrakisdimethyl-amidotitanium, tetraethylorthosilicate, and triethylphosphate; and
flowing the liquid phase material to the semiconductor tools from one of the first tank and the second tank comprises flowing the liquid phase material to chemical vapor deposition tools.
